(19) United States
(12) Patent Application Publication
(10) Pub. No.: US 2007/0218691 A1
(43) Pub. Date: Sep. 20, 2007

(54) PLASMA ETCHING METHOD, PLASMA ETCHING APPARATUS AND COMPUTER-READABLE STORAGE MEDIUM

(75) Inventor: Yuki Chiba, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/687,414

(22) Filed: Mar. 16, 2007

Related U.S. Application Data
(60) Provisional application No. 60/786,026, filed on Mar. 27, 2006.

(30) Foreign Application Priority Data
Mar. 17, 2006 (JP) 2006-075324

(51) Int. Cl. G01L 21/30; C23F 1/00; G06F 19/00; H01L 21/306; H01L 21/302

(52) U.S. Cl. 438/689; 216/67; 216/59; 156/345.24; 700/121

(57) ABSTRACT

A plasma etching method includes the step of performing a plasma etching on a CFₓ film formed on a substrate to be processed by using a plasma of an etching gas. A gaseous mixture including CF₄ and O₂ is employed as the etching gas. The etching gas further includes a hydrogen-containing gas and the hydrogen-containing gas is CH₃F or CH₂F₂. Further, a plasma etching apparatus includes a processing chamber; a processing gas supply unit; a plasma generating unit, thereby plasma processing the semiconductor substrate; and a control unit. Furthermore, in a computer-readable storage medium for storing therein a computer executable control program, the control program controls a plasma processing apparatus to perform the plasma etching method.

### FIELD OF THE INVENTION

The present invention relates to a plasma etching method for performing a plasma etching on a CFₓ film; and also relates to a plasma etching apparatus and a computer-readable storage medium to be used therefor.

### BACKGROUND OF THE INVENTION

Conventionally, a plasma etching for performing an etching on a target layer by using a plasma generated from an etching gas is widely employed in a manufacturing process of semiconductor devices. Further, a low-k film is used as an interlayer insulating film of a semiconductor device, and there is proposed a method of using a CFₓ film as the low-k film (see, for example, Japanese Patent Laid-open Application No. 2000-232158). To perform a plasma etching on the CFₓ film, there is known a method of using a gaseous mixture of N₂ and H₂ as an etching gas.

However, if trenches or the like are formed by plasma-etching the CFₓ film while using the gaseous mixture of N₂ and H₂ as the etching gas, there occurs a problem that micro trenches are formed at, e.g., bottom portions of the trenches.

### SUMMARY OF THE INVENTION

It is, therefore, an object of the present invention to provide a plasma etching method capable of suppressing a formation of micro trenches in a plasma etching of a CFₓ film; and also to provide a plasma etching apparatus for performing the plasma etching method and a computer-readable storage medium to be used therefor.

In accordance with a first aspect of the present invention, there is provided a plasma etching method including the step of: performing a plasma etching on a CFₓ film formed on a substrate to be processed by using a plasma of an etching gas, wherein a gaseous mixture including CF₄ and O₂ is employed as the etching gas.

It is preferable that the etching gas further includes a hydrogen-containing gas.

It is preferable that the hydrogen-containing gas is CH₃F or CH₂F₂.

In accordance with a second aspect of the present invention, there is provided a plasma etching apparatus including: a processing chamber for accommodating therein a semiconductor substrate to be processed; a processing gas supply unit for supplying an etching gas into the processing chamber; a plasma generating unit for converting the etching gas supplied from the processing gas supply unit into a plasma, thereby plasma processing the semiconductor substrate; and a control unit for controlling the above-mentioned plasma etching method to be carried out in the processing chamber.

In accordance with a third aspect of the present invention, there is provided a computer-readable storage medium for storing therein a computer executable control program, wherein the control program controls a plasma processing apparatus to perform the above-mentioned plasma etching method.

In accordance with the present invention, it is possible to provide a plasma etching method capable of suppressing a formation of micro trenches (a bottom portion of a trench becomes a hill shape with an excessively etched boundary portion between the bottom and the sidewall of the trench) in a plasma etching of a CFₓ film; and also to provide a plasma etching apparatus for performing the plasma etching method and a computer-readable storage medium to be used therefor.

### BRIEF DESCRIPTION OF THE DRAWINGS

The above and other objects and features of the present invention will become apparent from the following description of embodiments given in conjunction with the accompanying drawings, in which:

FIGS. 1A to 1C provide cross sectional views of a semiconductor wafer to which a plasma etching method in accordance with an embodiment of the present invention is applied;

FIG. 2 sets forth a schematic configuration view of a plasma etching apparatus in accordance with the embodiment of the present invention; and

FIG. 3 presents a diagram showing a micro trench formed in a comparative example.

### DETAILED DESCRIPTION OF THE EMBODIMENTS

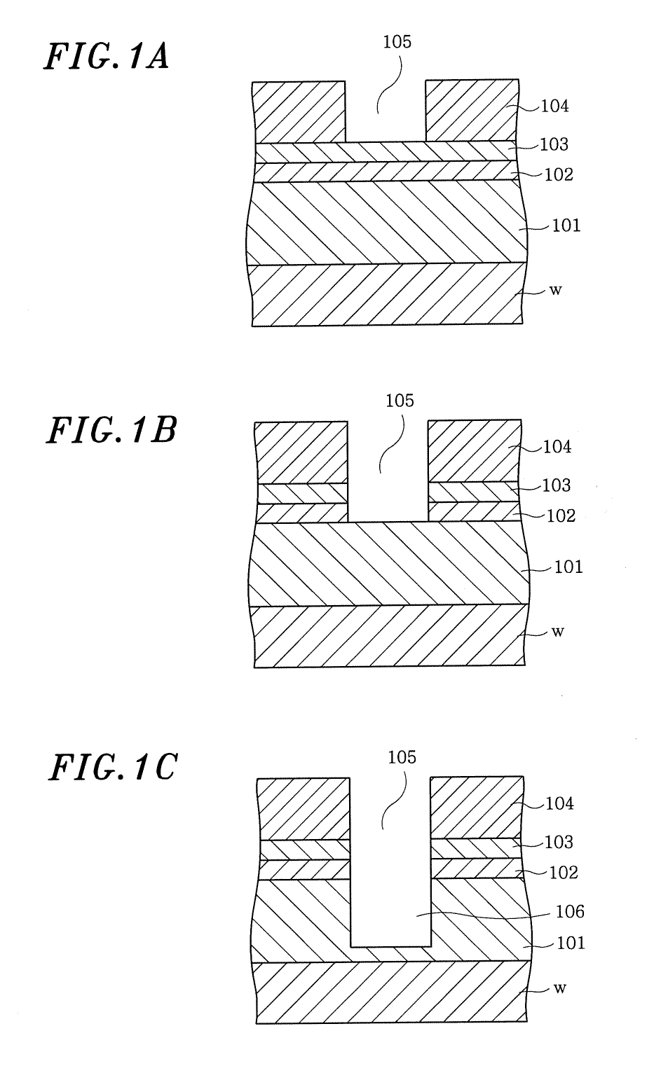

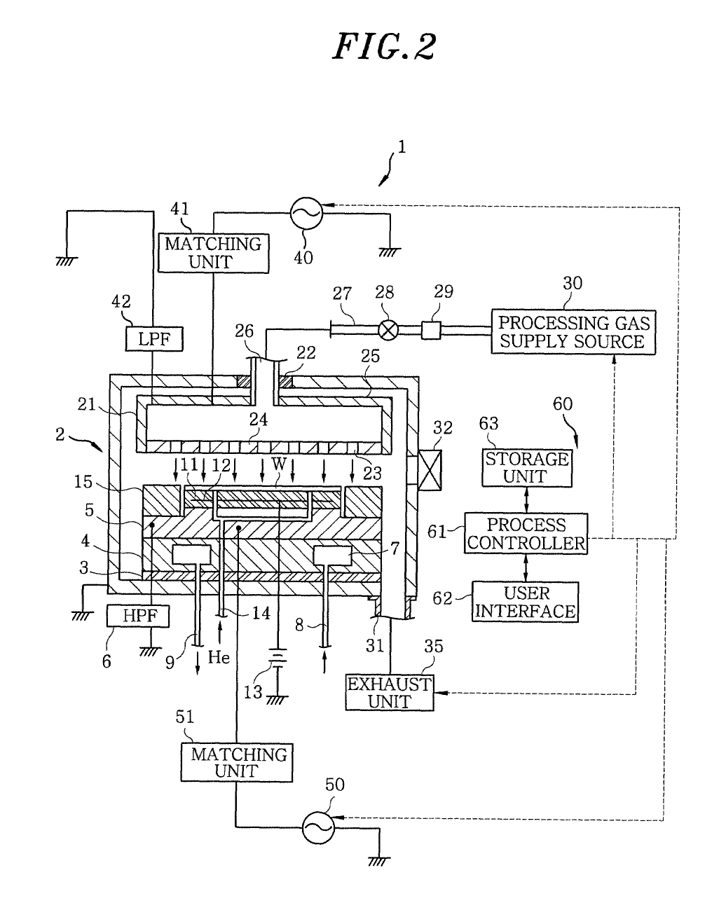

Hereinafter, an embodiment of the present invention will be described in detail with reference to the accompanying drawings. FIGS. 1A to 1C are enlarged cross sectional configuration views of a semiconductor wafer W which is used in a plasma etching method in accordance with an embodiment of the present invention. FIG. 2 illustrates a configuration of a plasma etching apparatus 1 in accordance with the embodiment of the present invention. Below, the configuration of the plasma etching apparatus 1 will be first explained with reference to FIG. 2.

The plasma etching apparatus 1 is configured as a capacitively coupled parallel plate type etching apparatus having an upper and a lower electrode plate placed to face each other in parallel and respectively connected to power supplies for plasma generation.

The plasma etching apparatus 1 has a cylindrical processing chamber (processing vessel) 2 formed of, for example, aluminum whose surface is anodically oxidized, and the processing chamber 2 is grounded. A substantially columnar susceptor support 4 for mounting thereon a target object to be processed, e.g., a semiconductor wafer W is installed at a bottom portion of the processing chamber 2 via an insulating plate 3 such as ceramic. Further, a susceptor 5 serving as a lower electrode is mounted on the susceptor support 4, and the susceptor 5 is connected to a high pass filter (HPF) 6.

A coolant path 7 is formed inside the susceptor supoort 4 to introduce a coolant via a coolant introducing line 8 and discharge it via a coolant discharge line 9. By this circulation of the coolant, the cold heat of the coolant is transferred to the semiconductor wafer W via the susceptor 5, whereby the wafer W is maintained at a desired temperature level.

The susceptor 5 has an upper central portion of a disk shape, which protrudes higher than its peripheral portion, and an electrostatic chuck 11 that is shaped substantially identical to the semiconductor wafer W is disposed on the upper central portion of the susceptor 5. The electrostatic chuck 11 includes an electrode 12 embedded in an insulating member. The semiconductor wafer W is electrostatically attracted and held by the electrostatic chuck 11 by, for example, a Coulomb force generated by applying a DC voltage of, for example, 1.5 kV to the electrode 12 from a DC power supply 13 connected thereto.

Further, formed through the insulating plate 3, the susceptor support 4, the susceptor 5 and the electrostatic chuck 11 is a gas channel 14 for supplying a heat transfer medium (for example, a He gas) to the rear surface of the semiconductor wafer W. The cold heat of the susceptor 5 is transferred from the susceptor 5 to the semiconductor wafer W through the heat transfer medium, so that the wafer W is maintained at the specific temperature level.

An annular focus ring 15 is disposed on the periphery of the top surface of the susceptor 5 to surround the semiconductor wafer W loaded on the electrostatic chuck 11. The focus ring 15 is formed of a conductive material such as silicon and serves to improve etching uniformity.

An upper electrode 21 is disposed above the susceptor 5, while facing it in parallel. The upper electrode 21 is supported at an upper portion of the processing chamber 2 via an insulating member 22. The upper electrode 21 includes an electrode plate 24; and an electrode support 25 that serves to support the electrode 24 and is made up of a conductive material. The electrode plate 24 is formed of, for example, aluminum whose surface is anodically oxidized (alumite treated) with a quartz cover attached thereto and is provided with a number of injection openings 23. The electrode plate 24 is configured to face the susceptor 5 and a distance between the susceptor 5 and the upper electrode 21 is adjustable.

A gas inlet port 26 is formed at a center of the electrode support 25 of the upper electrode 21, and a gas supply line 27 is coupled to the gas inlet port 26. Further, the gas supply line 27 is connected to a processing gas supply source 30 via a valve 28 and a mass flow controller 29. The processing gas supply source 30 supplies an etching gas for a plasma etching.

A gas exhaust line 31 is connected to a bottom portion of the chamber 2 and coupled to a gas exhaust unit 35. The gas exhaust unit 35 includes a vacuum pump such as a turbo molecular pump and is configured to be capable of vacuum exhausting an inside of the processing chamber 2 to a depressurized atmosphere, e.g., down to a pressure of 1 Pa or less. Further, a gate valve 32 is installed at a sidewall of the processing chamber 2. The semiconductor wafer W is transferred between the processing chamber 2 and an adjacent load lock chamber (not shown) while the gate valve 32 is opened.

A first high frequency power supply 40 is connected to the upper electrode 21 via a matching unit 41. Further, a low pass filter (LPF) 42 is connected to the upper electrode 21. The first high frequency power supply 40 is of a frequency ranging from about 50 to 150 MHz. By applying a high frequency power in such a frequency range, a high-density plasma in a desirable dissociated state can be generated in the processing chamber 2.

Further, a second high frequency power supply 50 is connected to the susceptor 5 serving as the lower electrode via a matching unit 51. The second high frequency power supply 50 has a frequency range lower than that of the first high frequency power supply 40. By applying such a frequency range, a proper ionic action can be facilitated without causing any damage on the semiconductor wafer W serving as a target object to be processed. Preferably, the frequency of the second high frequency power supply 50 is determined within a range from about 1 to 20 MHz.

The whole operation of the plasma processing apparatus 1 having the above-described configuration is controlled by a control unit 60. The control unit 60 includes a process controller 61 having a CPU for controlling each component of the plasma etching apparatus; a user interface 62; and a memory 63.

A user interface 62 includes a keyboard for a process manager to input a command to operate the plasma etching apparatus 1, a display for showing an operational status of the plasma etching apparatus 1 and the like.

Moreover, the memory 63 stores therein, e.g., control programs (software) and recipes including processing condition data and the like to be used in realizing various processes, which are performed in the plasma etching apparatus 1 under the control of the process controller 61. When a command is received from the user interface 62, the process controller 61 retrieves a necessary recipe from the memory 63 as required to execute the command to perform a desired process in the plasma processing apparatus 1 under the control of the process controller 61. The recipe such as the control program or the processing condition data can be retrieved from a computer-readable storage medium (for example, a hard disk, a CD, a flexible disk, a semiconductor memory, or the like), or also can be transmitted on-line from another apparatus via, e.g., a dedicated line, when necessary.

When performing a plasma etching on the semiconductor wafer W by using the plasma etching apparatus 1 having the above-described configuration, the gate valve 32 is first opened, and the semiconductor wafer W is loaded into the processing chamber 2 from the load lock chamber (not shown) and mounted on the electrostatic chuck 11. Then, a DC voltage is applied to the electrostatic chuck 11 from the DC power supply 13, whereby the semiconductor wafer W is electrostatically attracted by the electrostatic chuck 11 to be held thereon. Subsequently, the gate valve 32 is closed, and the processing chamber 2 is evacuated to a specific vacuum level by the gas exhaust unit 35.

Thereafter, the valve 28 is opened, and an etching gas is supplied into a hollow space of the upper electrode 21 via the gas supply line 27 and the gas inlet port 26 from the processing gas supply source 30 while its flow rate is controlled by the mass flow controller 29. Then, the etching gas is discharged uniformly toward the semiconductor wafer W through the injection openings 23 of the electrode plate 24, as indicated by arrows in FIG. 2.

Then, the inner pressure of the processing chamber 2 is maintained at a specific pressure level, and a high frequency power of a specific frequency is applied to the upper electrode 21 from the first high frequency power supply 40, whereby a high frequency electric field is generated between the upper electrode 21 and the susceptor 5 serving as the lower electrode. As a result, the etching gas is dissociated and converted into plasma.

Meanwhile, a high frequency power of a frequency lower than that from the first high frequency power supply 40 is applied to the susceptor 5 serving as the lower electrode from the second high frequency power supply 50. As a result, ions among the plasma are attracted toward the susceptor 5, so that etching anisotropy is improved by ion assist.

Then, upon the completion of the plasma etching, the supply of the high frequency powers and the processing gas is stopped, and the semiconductor wafer W is retreated out of the processing chamber 2 in the reverse sequence as described above.

Below, the plasma etching method in accordance with the embodiment of the present invention will be described with reference to FIGS. 1A to 1C which show cross sectional views of a semiconductor wafer W which is used as a substrate to be processed in experiments to be described later. As shown in FIG. 1A, on the surface of the semiconductor wafer W made up of silicon, there is formed a CFx film 101. Further, a SiCN film 102, a bottom antireflection coating (BARC) 103, a photoresist film 104 are formed from a lower side on the surface of the CFₓ film in this order. The photoresist film 104 is provided with an opening 105 for a trench formation.

The above-described structure of the semiconductor wafer W is exemplified as a sample for investigating an etching state of the CFₓ film 101, and in an actual semiconductor device manufacturing process, various films such as a SiCN film, an insulating film, and the like may be formed on or under the CFₓ film 101.

From the state shown in FIG. 1A, by performing a plasma etching on the BARC 103 and the SiCN film 102 while using the photoresist film 104 as a mask, the wafer state shown in FIG. 1B is obtained.

Then, the CFₓ film 101 is plasma-etched by using a gaseous mixture including CH₄ and O₂ as an etching gas, whereby a trench 106 is formed on the CFₓ film, as illustrated in FIG. 1C. Here, instead of the above-specified gaseous mixture including CH₄ and O₂, a gaseous mixture including CH₄, O₂ and an additive gas can be used as the etching gas for the plasma-etching of the CFₓ film 101. For example, a hydrogen-containing gas (such as CH₃F or CH₂F₂) can be employed as the additive gas. If the hydrogen-containing gas is added, H radicals increase, whereby an isotropic etching tendency becomes stronger, and, as a result, a generation of micro trenches can be suppressed. Further, in case an underlying layer present below the CFₓ film is, for example, a SiCN-based film or a SiCOH-based film, there is a likelihood that the underlying layer is etched and an etching profile deteriorates due to F radicals generated during the etching of the CFₓ film. However, the H radicals serve to remove the unnecessary F radicals, so that the deterioration of the etching profile can be prevented.

In an example, a plasma etching was performed on a semiconductor wafer (having a diameter of 20 cm) configured as illustrated in FIG. 1A by using the plasma etching apparatus shown in FIG. 2 according to a processing recipe to be specified below.

The processing recipe for the example is retrieved from the memory 63 of the control unit 60 and executed by the process controller 61. The process controller 61 controls each component of the plasma etching apparatus 1 based on a control program, whereby an etching process is performed according to the retrieved processing recipe as follows:

(Etching of the BARC 103)
etching gas: CF₄=100 sccm;
pressure=6.65 Pa (50 mTorr);
power (upper electrode/lower electrode)=1000/100 W;
temperature (lower electrode/upper electrode/chamber sidewall): 20/60/50° C.;
distance between the upper and the lower electrode=60 mm;
He pressure (center/edge)=1330/4655 Pa (10/35 Torr);
Etching time: 20 seconds

(Etching of the SiCN film 102)
etching gas: CH₂F₂/Ar/O₂=20/200/15 sccm;
pressure=6.65 Pa (50 mTorr);
power (upper electrode/lower electrode)=2000/100 W;
temperature (lower electrode/upper electrode/chamber sidewall)=20/60/50° C.;
distance between the upper and the lower electrode; 55 mm;
He pressure (center/edge)=1330/4655 Pa (10/35 Torr);
etching time: 25 seconds.

(Etching of the CFₓ film 101)
etching gas: CH₄/O₂=450/300 scam;
pressure=7.98 Pa (60 mTorr);
power (upper electrode/lower electrode)=2000/200 W;
temperature (lower electrode/upper electrode/chamber sidewall)=20/60/50° C.;
distance between the upper and the lower electrode=45 mm;
He pressure (center/edge)=1330/4655 Pa (10/35 Torr);
etching time=45 seconds.

In the above example, an etching rate of the CFₓ film 101 was 288 nm/min at a wafer center portion and 296 nm at a wafer edge portion. Further, when observed by an electron microscope, no micro trench was found at a trench 106 of the CFₓ film 101.

Then, as a comparative example, an etching of a BARC 103 and an etching of a SiCN film 102 were performed under the same processing conditions as those for the BARC 103 and the SiCN film 102 in the above experiment, while an etching of a CFₓ film 101 was performed under the following processing conditions:

(Etching of the CFx film 101)
etching gas: N₂/H₂=300/300 scam;
pressure: 3.99 Pa (30 mTorr);
power (upper electrode/lower electrode)=1500/200 W;
temperature (lower electrode/upper electrode/chamber sidewall)=20/60/50° C.;
distance between the electrode: 45 mm;
He pressure (center/edge)=1330/4655 Pa (10/35 Torr);
etching time: 30 seconds.

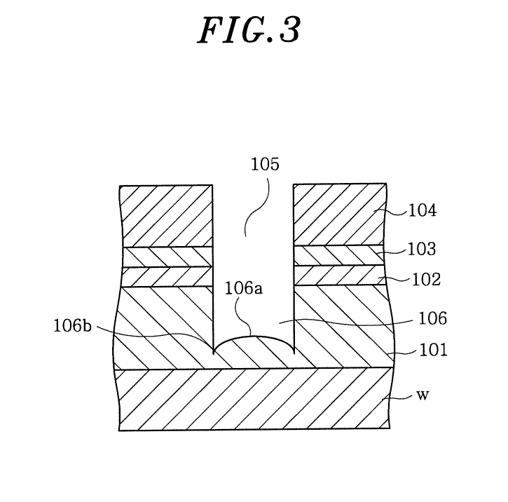

In comparative example, an etching rate of the CFₓ film 101 was 257 nm at a wafer center portion and 266 nm at a wafer edge portion. Further, as illustrated in FIG. 3, when observed by an electron microscope, a bottom portion 106a of a trench 106 of the CFₓ film 101 was found to have a hill shape with an excessively etched boundary portion 106b between the bottom and the sidewall of the trench 106, proving a presence of micro trenches.

In accordance with the embodiment of the present invention as described above, when performing a plasma-etching of the CFₓ film, a generation of micro trenches can be suppressed, in comparison with conventional cases. Further, it is to be noted that the present invention is not limited to the embodiment as described above but can be modified in various ways. For example, the plasma etching apparatus is not limited to the parallel plate type plasma etching apparatus as shown in FIG. 2 in which high frequency powers are respectively applied to the upper and the lower electrode; but, instead, any of other various types of plasma etching apparatuses can be utilized.

While the invention has been shown and described with respect to the embodiment, it will be understood by those skilled in the art that various changes and modifications may be made without departing from the scope of the invention as defined in the following claims.

What is claimed is:

1. A plasma etching method comprising the step of:
performing a plasma etching on a CFₓ film formed on a substrate to be processed by using a plasma of an etching gas,
wherein a gaseous mixture including CF₄ and O₂ is employed as the etching gas.

2. The plasma etching method of claim 1, wherein the etching gas further includes a hydrogen-containing gas.

3. The plasma etching method of claim 2, wherein the hydrogen-containing gas is CH₃F or CH₂F₂.

4. A plasma etching apparatus comprising:
a processing chamber for accommodating therein a semiconductor substrate to be processed;
a processing gas supply unit for supplying an etching gas into the processing chamber;
a plasma generating unit for converting the etching gas supplied from the processing gas supply unit into a plasma, thereby plasma processing the semiconductor substrate; and
a control unit for controlling the plasma etching method of claim 1 to be carried out in the processing chamber.

5. A plasma etching apparatus comprising:
a processing chamber for accommodating therein a semiconductor substrate to be processed;
a processing gas supply unit for supplying an etching gas into the processing chamber;
a plasma generating unit for converting the etching gas supplied from the processing gas supply unit into a plasma, thereby plasma processing the semiconductor substrate; and
a control unit for controlling the plasma etching method of claim 2 to be carried out in the processing chamber.

6. A plasma etching apparatus comprising:
a processing chamber for accommodating therein a semiconductor substrate to be processed;
a processing gas supply unit for supplying an etching gas into the processing chamber;
a plasma generating unit for converting the etching gas supplied from the processing gas supply unit into a plasma, thereby plasma processing the semiconductor substrate; and
a control unit for controlling the plasma etching method of claim 3 to be carried out in the processing chamber.

7. A computer-readable storage medium for storing therein a computer executable control program, wherein the control program controls a plasma processing apparatus to perform the plasma etching method of claim 1.

8. A computer-readable storage medium for storing therein a computer executable control program, wherein the control program controls a plasma processing apparatus to perform the plasma etching method of claim 2.

9. A computer-readable storage medium for storing therein a computer executable control program, wherein the control program controls a plasma processing apparatus to perform the plasma etching method of claim 3.
